(19) United States
(12) Patent Application Publication
(10) Pub. No.: US 2026/0354004 A1
(43) Pub. Date: Nov. 5, 2026

(54) SENSOR MOUNTING DEVICE, SENSOR MODULE AND DEPOSITION APPARATUS

(71) Applicant: LG Display Co., Ltd., Seoul (KR)

(72) Inventors: Ji-Man Seo, Paju-si (KR); Yunseon Kang, Paju-si (KR)

(73) Assignee: LG Display Co., Ltd., Seoul (KR)

(21) Appl. No.: 19/661,286

(22) Filed: Apr. 28, 2026

(30) Foreign Application Priority Data
Apr. 29, 2025 (KR) 10-2025-0055926

(51) Int. Cl. H10K 71/16; C23C 14/54; G01G 3/13

(52) U.S. Cl. CPC H10K 71/164; C23C 14/54; G01G 3/13

(57) ABSTRACT

The present disclosure relates to a sensor mounting device, a sensor module and a deposition apparatus. A sensor mounting device according to example embodiments of the present disclosure may include a plurality of sensors configured to identify a mass change of a material being deposited, a first holder including a plurality of first openings overlapping the plurality of sensors, a second holder including a plurality of second openings overlapping the plurality of sensors, and a disk on which the plurality of sensors are located, the disk including a plurality of third openings corresponding to respective shapes of the plurality of sensors, and positioned between the first holder and the second holder. The plurality of third openings respectively overlap the plurality of first openings and the plurality of second openings, and may be disposed in a first region in the disk having a first ring shape.

### CROSS REFERENCE TO RELATED APPLICATION

This application claims priority from and the benefit of Korean Patent Application No. 10-2025-0055926, filed on Apr. 29, 2025, which is hereby incorporated by reference for all purposes as if fully set forth herein.

### BACKGROUND

### Technical Field

Embodiments of the present disclosure relate to a sensor mounting device, a sensor module and a deposition apparatus, and more particularly, for example, without limitation, to a sensor module, a sensor mounting device and a deposition apparatus in which a cycle for replacing a plurality of sensors is reduced.

### Discussion of the Related Art

As the era of advanced information technology has arrived, the field of display technology, which visually represents electrical information signals, is developing in the direction of becoming thinner, lighter, and higher performance.

Such a display device displays an image by arranging a plurality of pixels in a matrix form. Here, each pixel includes a light emitting element and a pixel driving circuit composed of a plurality of transistors for independently driving the light emitting element.

Recently, research on thinner and lighter display panels has been actively conducted. Development of display devices in which a display panel is curved, folded, or unfolded using an organic light emitting display is also being conducted.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

In order to manufacture such an organic light emitting display, a deposition process of depositing an organic material is performed. As the organic material is exposed to internal pressure and thermal energy for a long time, the organic material is deformed, and problems regarding differences in panel performance accordingly have been raised.

During the deposition process, it may be determined whether deposition is normally performed according to an evaporation amount of the organic material. A sensor for determining whether deposition is normally performed may be included in a deposition apparatus.

However, replacement of the sensor may be required due to reasons such as the end of the lifespan of the sensor during the deposition process. Also, an operator may have to manually mount the sensor.

Accordingly, embodiments of the present disclosure are directed to a sensor mounting device, a sensor module and a deposition apparatus that substantially obviate one or more of the problems due to limitations and disadvantages of the related art.

An aspect of the present disclosure is to provide a sensor module, a sensor mounting device and a deposition apparatus in which a cycle for replacing a plurality of sensors is reduced.

Another aspect of the present disclosure is to provide a sensor module, a sensor mounting device and a deposition apparatus in which an operator does not manually mount a plurality of sensors.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and

broadly described herein, a sensor mounting device may comprise a plurality of sensors configured to identify a mass change of a material being deposited, a first holder including a plurality of first openings overlapping the plurality of sensors, a second holder including a plurality of second openings overlapping the plurality of sensors, and a disk on which the plurality of sensors are located, the disk including a plurality of third openings corresponding to respective shapes of the plurality of sensors, and positioned between the first holder and the second holder. The plurality of third openings may respectively overlap the plurality of first openings and the plurality of second openings, and may be disposed in a first region in the disk having a first ring shape.

In another aspect, a sensor module may comprise a carousel a disk and a plurality of sensors which are mounted on the disk, a first shaft to which the carousel is coupled, a motor configured to rotate the first shaft, and a housing disposed on the carousel and including an opening overlapping at least one sensor among the plurality of sensors.

In another aspect, a deposition apparatus may comprise a chamber, a sensor module disposed within the chamber and comprising a carousel comprising a disk and a plurality of sensors mounted on the disk, and a housing disposed on the carousel and including an opening overlapping at least one of the plurality of sensors and a crucible disposed within the chamber and containing a deposition material to be deposited on a substrate within the chamber.

The sensor module, the sensor mounting device and the deposition apparatus according to example embodiments of the present disclosure may reduce a cycle for replacing a plurality of sensors.

The sensor module, the sensor mounting device and the deposition apparatus according to example embodiments of the present disclosure may not manually mount a plurality of sensors.

According to example embodiments of the present disclosure, by providing a sensor mounting device with a reduced sensor replacement cycle, it is possible to provide a sensor mounting device capable of minimizing the number of times of Preventive Maintenance (PM) and increasing a continuous mass production period in an eco-friendly manner.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure, and together with the description serve to explain various principles.

FIG. 1 is a diagram illustrating a deposition apparatus according to various example embodiments of the present disclosure.

FIG. 2 is a diagram illustrating a sensor module according to an example embodiment of the present disclosure.

FIG. 3 is a diagram illustrating a carousel according to an example embodiment of the present disclosure.

FIG. 4 is a cross-sectional view of a partial region of a carousel according to an example embodiment of the present disclosure.

FIG. 5 is a diagram illustrating a sensor according to an example embodiment of the present disclosure.

FIG. 6 is a diagram illustrating a disk according to another example embodiment of the present disclosure.

FIG. 7 is a diagram illustrating a disk on which a conductive attachment part is disposed according to another example embodiment of the present disclosure.

FIG. 8 is a diagram illustrating a plurality of sensors and a disk according to another example embodiment of the present disclosure.

FIG. 9 is a diagram illustrating a process in which a plurality of sensors are coupled to a disk according to another example embodiment of the present disclosure.

FIG. 10 is a diagram illustrating a disk integrally formed with a plurality of sensors according to another example embodiment of the present disclosure.

FIG. 11 is a diagram illustrating components of a carousel including a disk according to another example embodiment of the present disclosure.

FIG. 12 is a diagram illustrating a carousel in which components are coupled according to another example embodiment of the present disclosure.

FIG. 13 is a diagram illustrating a sensor module including a disk according to another example embodiment of the present disclosure.

FIG. 14 is a flowchart illustrating operations of a controller controlling a sensor module including a disk according to another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The terms, such as “below,” “lower,” “above,” “upper” and the like, may be used herein to describe a relationship between element(s) or item(s) as illustrated in the drawings. It will be understood that the terms are spatially relative and based on the orientation depicted in the drawings

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example embodiments of the present disclosure will be described in detail with reference to the accompanying drawings.

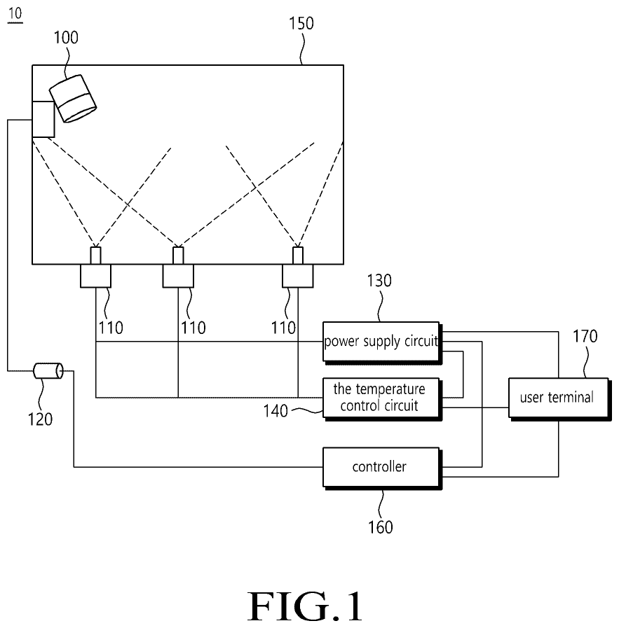

FIG. 1 is a diagram illustrating a deposition apparatus according to various example embodiments of the present disclosure.

Referring to FIG. 1, the deposition apparatus 10 may include a sensor module 100, a crucible 110, an oscillator 120, a power supply circuit 130, a temperature control circuit 140, a chamber 150, a controller 160, and a user terminal 170.

The deposition apparatus 10 may deposit a thin film on a substrate. The deposition apparatus 10 may monitor a thin film deposition process. The deposition apparatus 10 may be used in a manufacturing process such as a display module and a semiconductor process.

The sensor module 100 may be used to identify an evaporation rate of a material evaporated or vaporized in the crucible 110 or a deposition rate of a material deposited on a sensor. A unit of the deposition rate or the evaporation rate may be Angstroms per second (Å/S).

For example, the sensor module 100 may include a sensor including a quartz crystal, but is not limited thereto. For example, as the amount of deposited material increases, a resonance frequency may decrease. When an external material is deposited on the quartz crystal, the resonance frequency may change.

Using the changing resonance frequency, the amount of evaporated or deposited material may be identified. The amount of material deposited on the sensor per unit time and the amount of material evaporated from the crucible 110 per unit time may be proportional.

The amount of material deposited on the sensor per unit time and the amount of material deposited on the substrate according to the deposition process may be proportional. Accordingly, the deposition apparatus 10 may monitor a state (e.g., thickness) of the thin film deposited in the deposition process.

Hereinafter, one of the amount of material deposited on the sensor per unit time and the amount of material evaporated from the crucible 110 per unit time may be referred to as a deposition rate. In other words, the deposition apparatus 10 may identify, determine or decide at least one of the amount of material deposited on the sensor per unit time and the amount of material evaporated from the crucible 110 per unit time as the deposition rate.

For example, by identifying the deposition rate, the deposition apparatus 10 may monitor or adjust the deposition process.

For example, the number of sensor modules 100 may correspond to the number of crucibles 110. For example, the number of sensor modules 100 and the number of crucibles 110 may be the same, but is not limited thereto. For example, the number of sensor modules 100 may be different from the number of crucibles 110.

The crucible 110 may evaporate a material. For example, the crucible 110 may include a heating wire. The crucible 110 may boil an organic or inorganic material using the heating wire. The boiled material may be evaporated into the chamber 150. The evaporated material may form a thin film on the substrate in the chamber 150.

Depending on the size of the chamber 150, a plurality of crucibles 110 may be disposed in the chamber 150. The crucibles 110 may contain a deposition material to be deposited on a substrate within the chamber 150.

The oscillator 120 may provide an electronic signal (e.g., a clock signal, a reference frequency, a vibration wave) to the sensor module 100. The electronic signal may be provided to at least one sensor in the sensor module 100.

The power supply circuit 130 may provide power to other components of the deposition apparatus 10 such as the crucible 110, the temperature control circuit 140, the controller 160.

The temperature control circuit 140 may control the temperature of the sensor module 100 or the crucible 110. For example, the resonance frequency of the sensor including the quartz crystal in the sensor module 100 may be affected by temperature. According to the temperature control of the temperature control circuit 140, the controller 160 may identify the resonance frequency of the sensor within a stable constant temperature.

For example, the temperature control circuit 140 may change the temperature of at least a portion (e.g., the heating wire) in the crucible 110 to a temperature for depositing the organic material or inorganic material in the crucible 110.

The chamber 150 may include a space where a process proceeds. The chamber 150 may be in a vacuum state.

The controller 160 may control other components such as the oscillator 120, the sensor module 100 in the deposition apparatus 10. The controller 160 may include a monitor, but is not limited thereto.

For example, the controller 160 may identify at least one of a thin film deposition thickness, a deposition speed, or a mass change rate using the sensor in the sensor module 100.

For example, the controller 160 may adjust at least one of temperature, pressure, gas flow rate, power, and substrate rotation speed in the chamber 150. The monitor of the controller 160 may display at least one of temperature, pressure, gas flow rate, power, and substrate rotation speed.

The user terminal 170 may be any one of a TV (Television) system, a set-top box, a navigation system, a personal computer (PC), a home theater system, a mobile device, and a wearable device. The user terminal 170 may transmit a command according to a user's input to the power supply circuit 130, the temperature control circuit 140, and the controller 160. For example, the user terminal 170 may transmit a command according to a user's input to one or more of the power supply circuit 130, the temperature control circuit 140, and the controller 160.

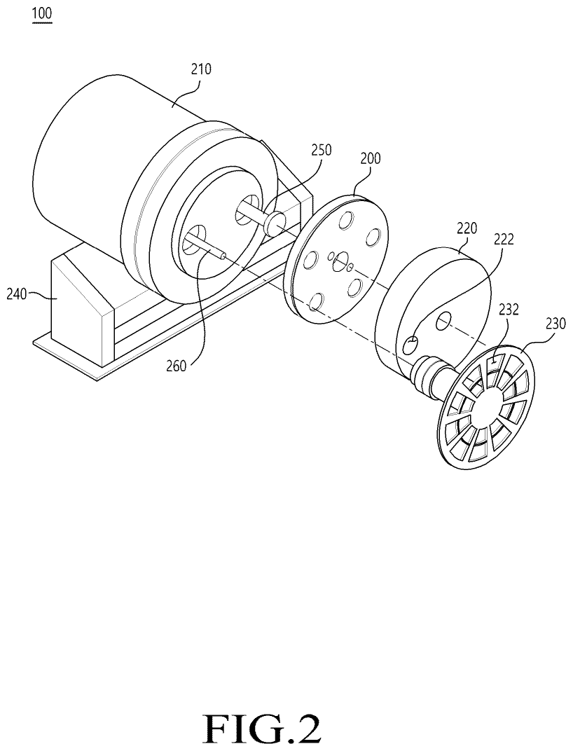

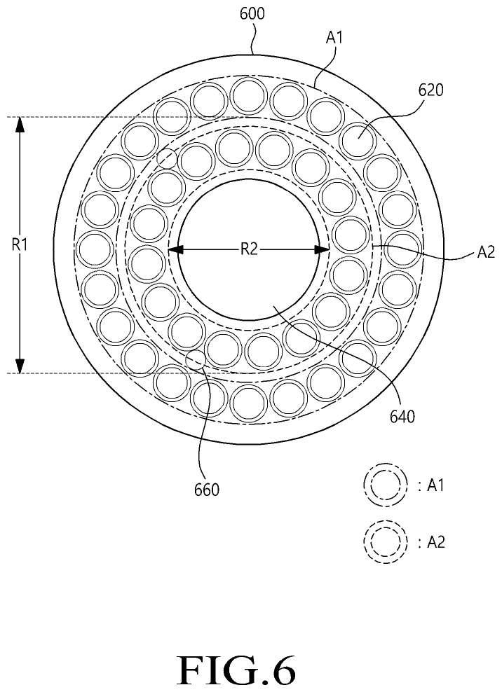

Hereinafter, various embodiments of the sensor module 100 of FIG. 1 will be described. An example embodiment of the sensor module 100 will be described with reference to FIGS. 2 to 5, and another example embodiment of the sensor module 100 will be described with reference to FIGS. 6 to 14.

FIG. 2 is a diagram illustrating the sensor module 100 according to an example embodiment of the present disclosure.

As one example, the sensor module 100 may include a carousel 200 comprising a disk and a plurality of sensors mounted on the disk; a first shaft 250 to which the carousel 200 is coupled; a motor 210 configured to rotate the first shaft 250; and a housing 220 disposed on the carousel 200 and comprising an opening overlapping at least one sensor among the plurality of sensors mounted on the disk, but is not limited thereto. More or less components can be included.

For example, referring to FIG. 2, the sensor module 100 may include a carousel 200, a motor 210, a housing 220, a chopper 230, a fixing device 240, a first shaft 250, and a second shaft 260. The sensor module 100 may be referred to as a QCM module (Quartz Crystal Microbalance Module).

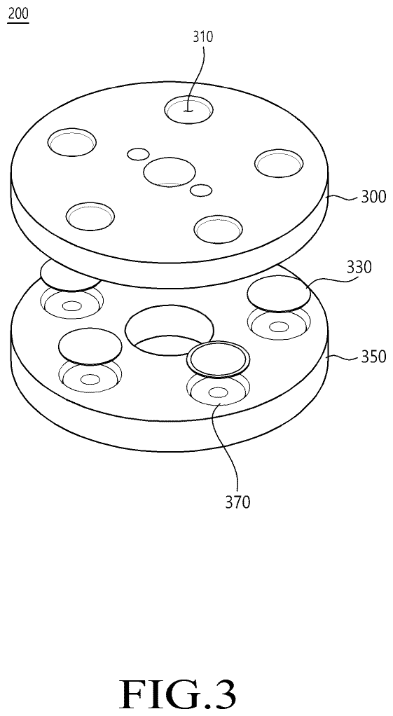

A plurality of sensors may be mounted on the carousel 200. For example, the carousel 200 may comprise a disk and a plurality of sensors mounted on the disk. A detailed description thereof may be illustrated in FIG. 3 and below.

The motor 210 may be configured to rotate the first shaft 250 and/or the second shaft 260. Based on rotating the first shaft 250, the motor 210 may rotate one of the carousel 200 and the housing 220. For example, the motor 210 may be configured to rotate the first shaft 250. The first shaft 250 may be coupled to the carousel 200 or the housing 220. Accordingly, the carousel 200 or the housing 220 may rotate. For example, the motor 210 may rotate the carousel 200. Based on rotating the second shaft 260, the motor 210 may rotate the chopper 230. For example, the motor 210 may be configured to rotate the second shaft 260. The second shaft 260 may be coupled to the chopper 230. Accordingly, the chopper 230 may rotate.

The housing 220 may be disposed on the carousel 200. The housing 220 may include at least one opening 222.

The opening 222 of the housing 220 may overlap a sensor in the carousel 200.

Accordingly, when the carousel 200 or the housing 220 is rotated, the plurality of sensors may be sequentially exposed one by one into the chamber 150. The evaporated material may be deposited on one exposed sensor. For example, the evaporated material may be deposited on exposed sensor one by one.

The chopper 230 may include at least one opening 232. For example, the size of the opening 232 of the chopper 230 may be different from the size of the opening of the carousel 200. Accordingly, the amount of material deposited on the sensor may be adjusted.

The fixing device 240 may fix other components such as the motor 210 in the sensor module 100 to one side in the chamber 150.

The first shaft 250 may be coupled to the carousel 200 or the housing 220. The motor 210 may be configured to rotate the first shaft 250. Accordingly, based on rotating the first shaft 250, the carousel 200 or the housing 220 may rotate.

The second shaft 260 may be coupled to the chopper 230. The motor 210 may be configured to rotate the second shaft 260. Accordingly, based on rotating the second shaft 260, the chopper 230 may rotate.

Hereinafter, the carousel 200 included in the sensor module 100 will be described in more detail with reference to FIG. 3.

FIG. 3 is a diagram illustrating the carousel according to an example embodiment of the present disclosure.

Referring to FIG. 3, the carousel 200 may include a first holder 300, a second holder 350, and a sensor 330. The carousel 200 may be referred to as a sensor mounting device.

The first holder 300 may include a plurality of first openings 310. The second holder 350 may include a plurality of second openings 370.

The plurality of first openings 310 may overlap the plurality of sensors 330 and the plurality of second openings 370.

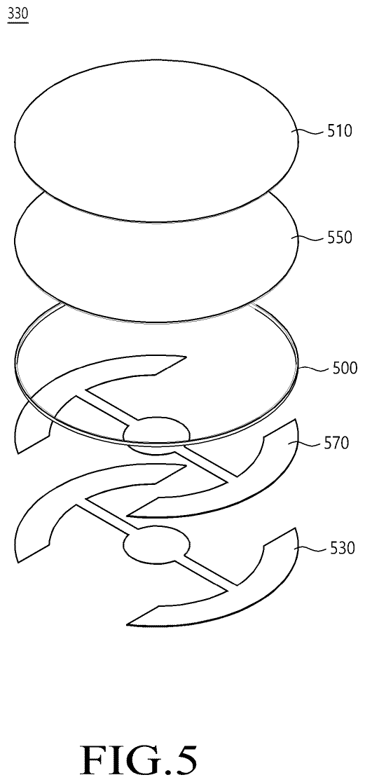

The sensor 330 may include a quartz crystal. A description of components of the sensor 330 may be illustrated in the description of FIG. 5.

The sensor 330 may receive an electronic signal provided from the oscillator 120 and resonate. The resonance frequency of the quartz crystal may be inversely proportional to the amount of deposited external material.

Accordingly, the controller 160 may identify the resonance frequency of the sensor 330 to identify the deposition amount of the deposition material per time.

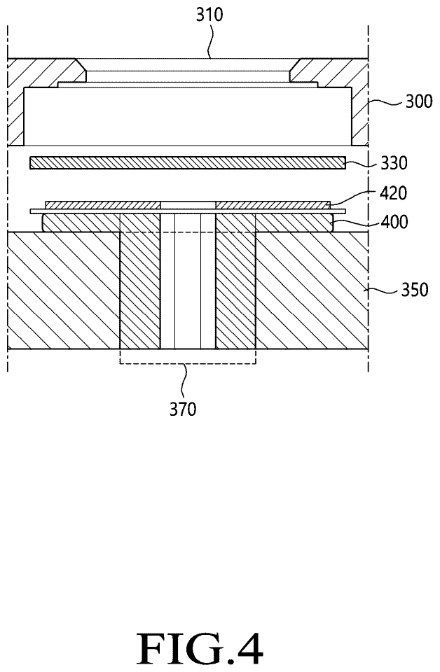

Hereinafter, a detailed structure of a region where one sensor 330 exists in the carousel 200 of FIG. 3 will be described in more detail with reference to FIG. 4.

FIG. 4 is a cross-sectional view of a partial region of the carousel according to an example embodiment of the present disclosure.

Referring to FIG. 4, the carousel 200 may include the first holder 300, the second holder 350, the sensor 330, an insulating part 400, and a spring electrode 420.

For example, the first opening 310 may be formed in the first holder 300, and the second opening 370 may be formed in the second holder 350.

For example, the insulating part 400 may be disposed on an inner side and an upper side of the second opening 370.

For example, the insulating part 400 may include one of Teflon (PTFE, Polytetrafluoroethylene), PPS (Polyphenylene Sulfide), Alumina and POM (Polyoxymethylene) or their combination, but is not limited thereto. For example, the insulating part 400 may be formed of Teflon.

At least a portion of the spring electrode 420 may be surrounded by the insulating part 400. Other portion of the spring electrode 420 may be disposed on the insulating part 400. The other portion of the spring electrode 420 may be in contact with the sensor 330.

For example, the spring electrode 420 may include a pillar part (not shown) and an electrode part (not shown). For example, the pillar part may be surrounded by the insulating part 400. For example, the electrode part may be disposed on the insulating part 400. The electrode part may be in contact with the sensor 330.

For example, a hole to which a bolt can be coupled may be formed in the pillar part. When the bolt is coupled, the spring electrode 420 and the second holder 350 may be coupled. The sensor 330 may be in contact with the spring electrode 420.

Hereinafter, the sensor 330 in contact with the spring electrode 420 will be described in detail by way of example with reference to FIG. 5. As the spring electrode 420 and the sensor 330 are in contact, the deposition rate may be determined using a current.

FIG. 5 is a diagram illustrating the sensor according to an example embodiment of the present disclosure.

Referring to FIG. 5, the sensor 330 may include a quartz layer 500, a first electrode 510, a second electrode 530, a first attachment layer 550, and a second attachment layer 570.

The quartz layer 500 may include a quartz crystal, but is not limited thereto. As described above, the deposition rate of the deposition material may be identified using the resonance frequency of the quartz crystal.

The first electrode 510 and the second electrode 530 may apply an AC voltage to the quartz layer 500. Accordingly, the quartz layer 500 may be vibrated by a piezoelectric effect.

The quartz layer 500 may be disposed between the first electrode 510 and the second electrode 530. The first electrode 510 may be disposed on the quartz layer 500. The second electrode 530 may be disposed under the quartz layer 500.

A material may not be well attached or deposited on a surface of the quartz layer 500. Accordingly, a configuration (e.g., the first attachment layer 550, the second attachment layer 570) for better attaching or depositing the material on the surface of the quartz layer 500 may be required.

The first attachment layer 550 may be disposed on the quartz layer 500. The material may be deposited on the first attachment layer 550. For example, the first attachment layer 550 may be disposed between the first electrode 510 and the quartz layer 500.

The second attachment layer 570 may be disposed below the quartz layer 500. The second attachment layer 570 may be disposed between the quartz layer 500 and the second electrode 530. A material may be deposited on the second attachment layer 570.

The first adhesion layer 550 and the second adhesion layer 570 may include a metal such as chromium (Cr), titanium (Ti), titanium tungsten (TiW), nickel (Ni), tantalum, or molybdenum (Mo), or an alloy such as nickel-chromium (NiCr), which has conductivity and high oxygen affinity capable of improving adhesion, but it is not limited thereto. For example, the first attachment layer 550 and the second attachment layer 570 may be formed of chromium (Cr).

In the case of using the carousel 200 illustrated in FIGS. 3 to 5, an operator may have to directly place the sensor 330 between the first holder 300 and the second holder 350. Accordingly, an error may occur in the placement of the sensor 330.

Hereinafter, a sensor mounting device or a carousel capable of accurately replacing the sensor 330 by replacing a disk integrally formed with the sensor 330 instead of placement by the operator may be illustrated in more detail.

In addition, since the first holder 300 and the second holder 350 do not have elasticity, contact resistance may occur between the sensor 330 and the first holder 300.

For example, since the first holder 300 and the second holder 350 do not have elasticity, when the position of the sensor 330 is changed from a predetermined position to another position, strong contact may occur between the sensor 330 and other components.

Due to the strong contact generated as the sensor is disposed at a different position rather than being disposed at the predetermined position, stronger contact resistance may occur between the sensor 330 and other components.

For example, strong contact resistance may occur between the sensor 330 and the spring electrode 420. For example, strong contact resistance may occur between the sensor 330 and the second holder 350. For example, strong contact resistance may occur between the sensor 330 and the first holder 300. For example, contact resistance may increase.

If the contact resistance increases, impedance may be generated by an AC signal. Accordingly, the controller 160 may not be able to accurately determine the deposition rate. In other words, performance of identifying the resonance frequency may deteriorate.

Hereinafter, a disk formed of metal for preventing the increase in contact resistance described above may be illustrated.

In addition, since the plurality of sensors 330 are disposed only in one ring-shaped region in the carousel 200, the number of sensors 330 disposed in one carousel 200 may be limited.

Recently, as the deposition process advances, the evaporation rate is increasing. As the number of sensors 330 is limited, the chopper 230 may be used in the sensor module 100.

When the chopper 230 is used, the deposition rate of the material deposited or attached on the sensor 330 may be reduced. Accordingly, the lifespan of the sensor 330 may be improved.

However, when the deposition rate of the material deposited on the sensor 330 is reduced, a Signal to Noise Ratio (SNR) may decrease.

The Signal to Noise Ratio (SNR) may be calculated as in the following equation 1.

$$S N R = 10 \times log \frac{Signal}{Noise} [ dB ] \qquad [ Equation 1 ]$$

The signal to noise ratio may be a massive characteristic. For example, as the signal to noise ratio has a high value, the deposition apparatus 10 may stably determine the deposition rate.

Therefore, as the chopper 230 is used, the deposition apparatus 10 may not be able to stably determine the deposition rate (or evaporation rate).

If the deposition rate cannot be stably determined, the quality of a product produced by the deposition process may deteriorate.

Hereinafter, the sensor module 100 according to another example embodiment of the present disclosure will be described in more detail with reference to FIGS. 6 to 14.

FIGS. 6 to 13 are diagrams for explaining the sensor module 100 according to other example embodiments of the present disclosure and internal components thereof.

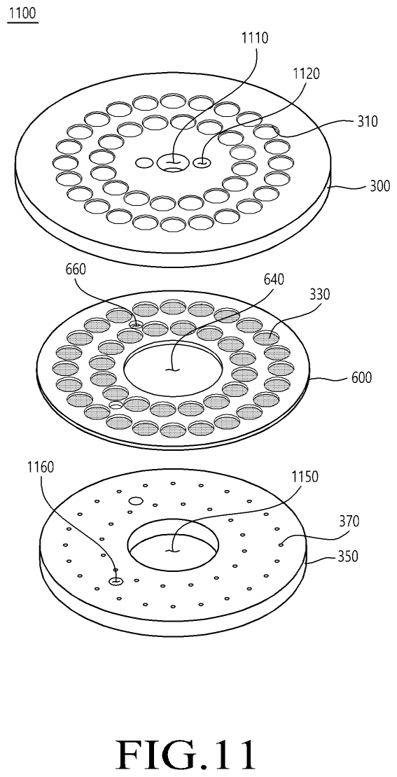

Referring to FIGS. 6 to 13, the sensor module 100 according to other example embodiments of the present disclosure may include the carousel 1100 of FIG. 11 having a structure different from that of the carousel 200 of FIG. 2, although its function or role is similar, in the sensor module 100 according to another example embodiment. As mentioned above, such a carousel 1100 may also be referred to as a sensor mounting device.

Referring to FIG. 11, in the sensor module 100 according to other example embodiments of the present disclosure, the carousel 1100 may include not only the first holder 300 and the second holder 350 but also a disk 600 disposed between the first holder 300 and the second holder 350.

Since the carousel 1100 further includes the disk 600, the sensors 330 can be more stably disposed, and electrically, contact resistance of the sensors 330 can be reduced, thereby increasing a signal-to-noise ratio (SNR) of the sensors 330.

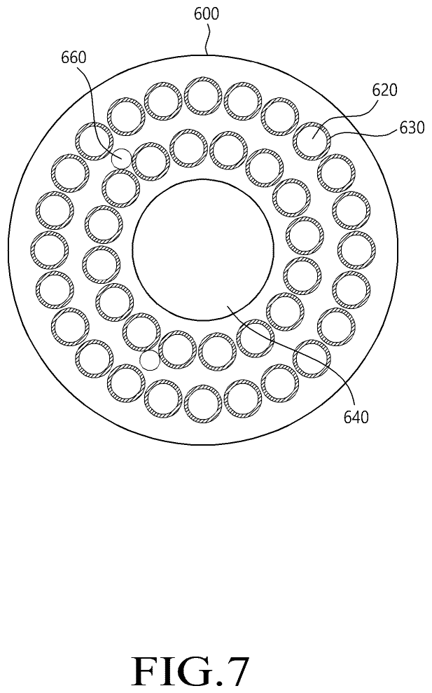

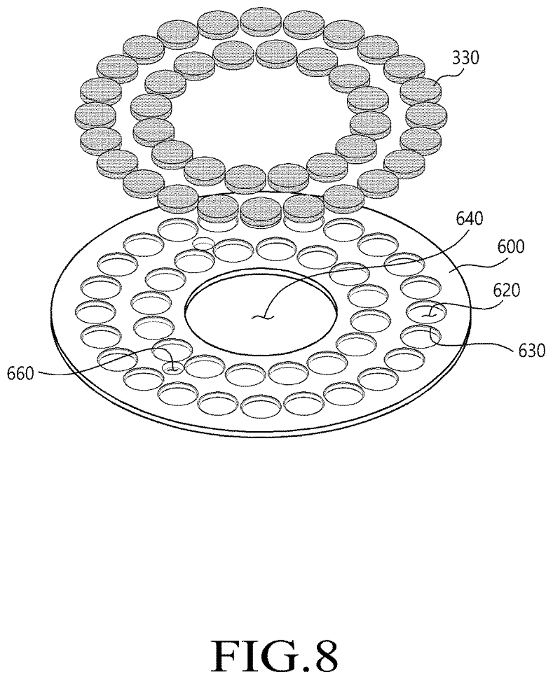

In the sensor module 100 according to other example embodiments of the present disclosure, a structure of the disk 600 included in the carousel 1100 will be described in more detail later with reference to FIGS. 6 and 7, and an example of a process for coupling the disk 600 and the sensors 330 will be described in more detail later with reference to FIGS. 8, 9, and 10.

FIG. 6 is a diagram illustrating the disk according to another example embodiment of the present disclosure.

As one example, the disk 600 may include a plurality of third openings 620 and a third central hole 640, and the plurality of sensors 330 may be located on the plurality of third openings 620. Referring to FIG. 6, the disk 600 may include a plurality of third openings 620, a third central hole 640, and at least one third coupling opening 660, but is not limited thereto.

The disk 600 may be formed of at least one metal among copper, stainless steel, and iron, but is not limited thereto. For example, the disk 600 formed of at least one metal among copper, stainless steel, and iron may have elasticity. However, the present disclosure is not limited to the presented example, and the disk 600 may be formed of a metal or alloy having elasticity. For example, since the first holder 300 and the second holder 350 do not have elasticity, when the position of the sensor 330 is changed from a predetermined position to another position, strong contact may occur between the sensor 330 and other components. The disk 600 may reduce strong contact between the sensor 330 and other components due to its elasticity.

Accordingly, an increase in the contact resistance between the plurality of sensors 330 and the first holder 300 may be minimized. An increase in the contact resistance between the plurality of sensors 330 and the second holder 350 may be also minimized. An increase in contact resistance between the plurality of sensors 330 and the spring electrode 420 may be also minimized.

The plurality of sensors 330 may be disposed in the plurality of third openings 620. For example, each of the plurality of third openings 620 may correspond to the size of the sensor 330.

The third central hole 640 may be coupled to the first shaft 250.

The third coupling opening 660 may be a space to which a fastening part coupling the second holder 350 and the disk 600 is coupled.

As one example, the disk 600 may include a plurality of regions having a ring shape. For example, the disk 600 may include two regions having a ring shape, such as a first region A1 having a first ring shape, and a second region A2 having a second ring shape, but is not limited thereto. The second region A2 is disposed between the first region A1 and the third central hole 640.

A diameter R2 of the second ring shape may be smaller than a diameter R1 of the first ring shape.

The plurality of third openings 620 may be disposed in the first region A1 and the second region A2. The plurality of sensors may be located in the plurality of third openings 620. The plurality of third openings 620 may be disposed in the first region A1. The plurality of third openings 620 may be disposed in the second region A2.

As the plurality of third openings 620 are disposed in regions having a plurality of ring shapes such as the first region A1 and the second region A2, a larger number of the plurality of sensors 330 may be disposed than when disposing the plurality of sensors 330 in a region having one ring shape in the sensor module 100.

Accordingly, it may not be necessary to use the chopper 230 to delay a replacement cycle of the sensor 330.

In addition, since the deposition rate of the material deposited or attached on the sensor 330 is not reduced, the signal-to-noise ratio (SNR) may increase.

An increase in the signal-to-noise ratio (SNR) may mean that noise decreases. Therefore, the deposition apparatus 10 may more accurately determine the deposition rate of the material.

The number of the plurality of third openings 620 disposed in the second region A2 may be different from the number of the plurality of third openings 620 disposed in the first region A1. The number of the plurality of third openings 620 disposed in the second region A2 may be smaller than the number of the plurality of third openings 620 disposed in the first region A1, but is not limited thereto.

For example, the number of the plurality of third openings 620 disposed in the first region A1 may be 24. The number of the plurality of third openings 620 disposed in the second region A2 may be 16. However, the number of the plurality of third openings 620 disposed in the first region A1 and the number of the plurality of third openings 620 disposed in the second region A2 are not limited to the presented numbers.

For example, the shape and the size of the plurality of third openings 620 disposed in the first region A1 and the shape and the size of the plurality of third openings 620 disposed in the second region A2 may be the same or different.

As one example, the size of the sensor 330 disposed in the plurality of third openings 620 disposed in the second region A2 may be different from the size of the sensor 330 disposed in the plurality of third openings 620 disposed in the first region A1. For example, the size of the sensor 330 disposed in the plurality of third openings 620 disposed in the second region A2 may be smaller than the size of the sensor 330 disposed in the plurality of third openings 620 disposed in the first region A1, but is not limited thereto.

For example, the disk 600 may include N regions (Nis 2 or a natural number greater than 2) having N ring shapes as well as the first region A1 and the second region A2. In this case, as a ring-shaped region is added, the diameter of the added ring-shaped region may gradually decrease. Alternatively, the number of third openings 620 disposed in the added ring-shaped region may gradually decrease. In addition, the size of the sensors 330 disposed in the added ring-shaped region may gradually decrease. For example, the size of the sensors 330 disposed in the N regions having N ring shapes may be smaller than that in the first region A1 and the second region A2.

For example, the disk 600 may include a third region having a third ring shape. For example, a diameter of the third ring shape may be smaller than the diameter R2 of the second ring shape. For example, the plurality of third openings 620 may be disposed in the third region.

For example, the number of the plurality of third openings 620 disposed in the third region may be smaller than the number of the plurality of third openings 620 disposed in the second region A2. For example, the size of the plurality of third openings 620 disposed in the third region and the size of the plurality of third openings 620 disposed in the second region A2 may be the same or different. For example, the size of the sensor 330 disposed in the plurality of third openings 620 disposed in the third region may be smaller than the size of the sensor 330 disposed in the plurality of third openings 620 disposed in the second region A2, but is not limited thereto.

Also, placing the sensors directly by the operator may reduce the efficiency of the deposition apparatus 10. In addition, when the lifespan of the sensors 330 in the carousel 1100 ends, if only the integrated disk is replaced, the time for replacing the plurality of sensors 330 may be shortened.

Hereinafter, a process for integrally forming the plurality of sensors 330 and the disk 600 may be illustrated.

FIG. 7 is a diagram illustrating the disk 600 on which a conductive attachment part 630 is disposed according to another example embodiment of the present disclosure. FIG. 8 is a diagram illustrating the plurality of sensors 330 and the disk 600 according to another example embodiment of the present disclosure.

In the description of FIGS. 7 and 8, descriptions overlapping with the description in FIG. 6 may be omitted.

Referring to FIG. 7, the conductive attachment part 630 may be disposed in each of the plurality of third openings 620. The conductive attachment part 630 may attach the sensor 330 and the third openings 620. For example, the conductive attachment portion 630 may be one of an anisotropic conductive film (ACF), an anisotropic conductive paste (ACP), and an isotropic conductive adhesive (ICA). For example, the conductive attachment portion 630 may be formed of an anisotropic conductive film.

Referring to FIG. 8, each of the plurality of sensors 330 may be disposed at a position corresponding to each of the plurality of third openings 620.

Hereinafter, a process in which the plurality of sensors 330 are integrally coupled with the plurality of third openings 620 may be illustrated.

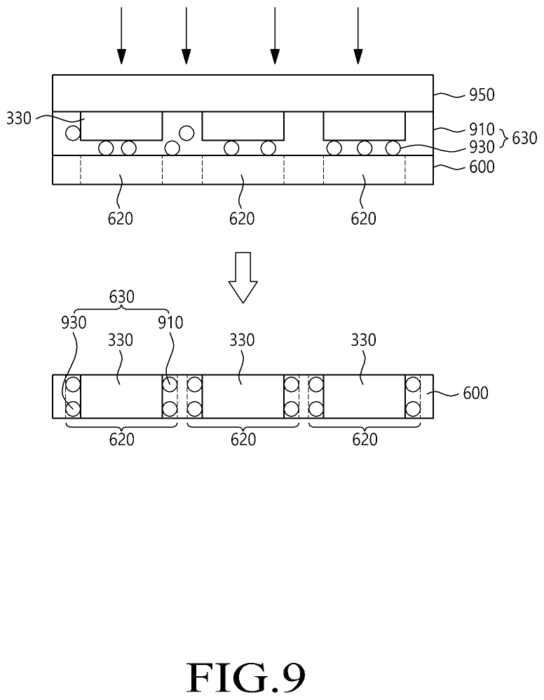

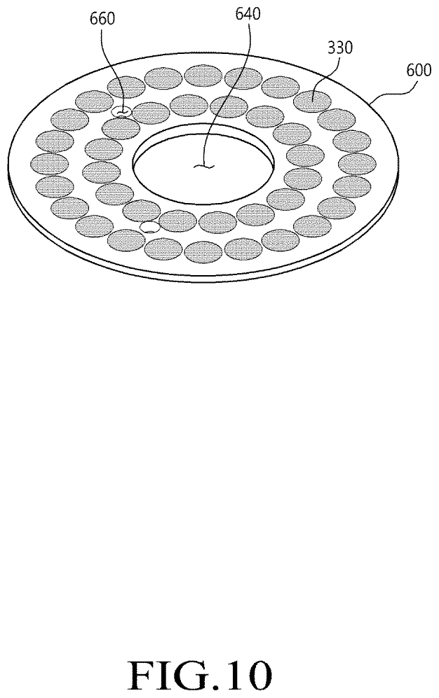

FIG. 9 is a diagram illustrating a process in which the plurality of sensors 330 are coupled to the disk 600 according to another example embodiment of the present disclosure. FIG. 10 is a diagram illustrating a disk integrally formed with a plurality of sensors according to another example embodiment of the present disclosure.

Referring to FIG. 9, the disk 600 and the plurality of sensors 330 may receive pressure by a pressing part 950. Also, the disk 600 and the plurality of sensors 330 may receive heat.

The conductive attachment part 630 may include a conductive ball 930 and an adhesive insulator 910. The conductive ball 930 may be a fine particle allowing current to pass.

At least a portion of the conductive attachment part 630 may be removed from the third opening 620 after receiving heat and pressure. Another portion of the conductive attachment portion 630 may remain in the third opening 620 after receiving heat and pressure, and the conductive attachment part 630 may be arranged within each of the plurality of third openings 620 as described above with reference to FIG. 7. For example, the disk 600 and the plurality of sensors 330 may be integrally formed after receiving heat and pressure.

Referring to FIG. 10, the plurality of third openings 620 in the disk 600 and the plurality of sensors 330 may be coupled. Accordingly, variation in the positions of the plurality of sensors 330 may be minimized. When the position variation of the plurality of sensors 330 is minimized, variation in the contact resistance may also be minimized.

Also, the operator may not need to place each of the plurality of sensors 330. For example, when the lifespan of the plurality of sensors 330 ends, by replacing the disk 600 coupled with the plurality of sensors 330, the plurality of sensors 330 can be accurately mounted in the carousel 200.

Hereinafter, the carousel 1100 including the disk 600 illustrated in FIGS. 6 to 10 may be illustrated. In the sensor module 100 according to other example embodiments of the present disclosure, the carousel 1100 may include the first holder 300 and the second holder 350, and the disk 600 between the first holder 300 and the second holder 350.

FIG. 11 is a diagram illustrating components of the carousel including the disk according to various example embodiments of the present disclosure.

Referring to FIG. 11, the carousel 1100 may include the first holder 300, the plurality of sensors 330, the second holder 350, and the disk 600 between the first holder 300 and the second holder 350.

The first holder 300 may include the plurality of first openings 310, a first central hole 1110, and at least one first coupling opening 1120.

The first central hole 1110 and the at least one first coupling opening 1120 may be coupled to the first shaft 250.

The second holder 350 may include the plurality of second openings 370, at least one second coupling opening 1160, and a second central hole 1150.

The second central hole 1150 may be a space for the first shaft 250 to pass through.

The disk 600 may include the plurality of third openings 620 overlapping with the plurality of first openings 310 and the plurality of second openings 370, the third central hole 640, and at least one third coupling opening 660.

The third central hole 640 may be a space for the first shaft 250 to pass through.

The second coupling opening 1160 and the third coupling opening 660 may be spaces where a fastening part coupling the second holder 350 and the disk 600 is fastened. For example, the fastening part may be a bolt. The second coupling opening 1160 and the third coupling opening 660 may be nuts, but is not limited thereto. Other components which can couple the second holder 350 and the disk 600 may be possible. Accordingly, the disk 600 and the second holder 350 may be coupled.

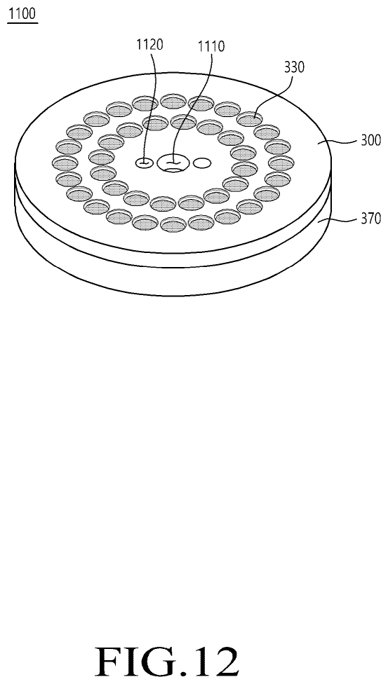

FIG. 12 is a diagram illustrating the carousel 1100 in which components are coupled according to another example embodiment of the present disclosure.

Referring to FIG. 12, when the components of the carousel 1100 are coupled, the plurality of first openings 310, the plurality of second openings 370, the plurality of sensors 330 disposed in the first region A1 and the second region A2, and the plurality of third openings 620 may overlap. For example, the plurality of first openings 310 and the plurality of second openings 370 may overlay with the plurality of sensors 330 disposed in the first region A1 having a first ring shape and a second region A2 having a second ring shape, but is not limited thereto.

The first holder 300 in FIG. 11 may further include the first openings 310 than the first holder 300 in FIG. 3. The second holder 350 in FIG. 11 may further include the second openings 370 than the second holder 350 in FIG. 3. For example, the first holder 300 in FIG. 11 may include more first openings 310 than the first holder 300 in FIG. 3. The second holder 350 in FIG. 11 may include more second openings 370 than the second holder 350 in FIG. 3.

The first central hole 1110, the second central hole 1150, and the third central hole 640 may overlap. Also, the first central hole 1110, the second central hole 1150, and the third central hole 640 may overlap a central hole of the housing 220.

The carousel 1100 or sensor mounting device according to one embodiment has been described with reference to FIGS. 6 through 12.

As described above, the carousel 1100 according to one embodiment includes a disk 600, thereby enabling more stable placement of the sensors 330 and reducing the electrical contact resistance of the sensors 330 and increasing the signal-to-noise ratio (SNR) of the sensors 330.

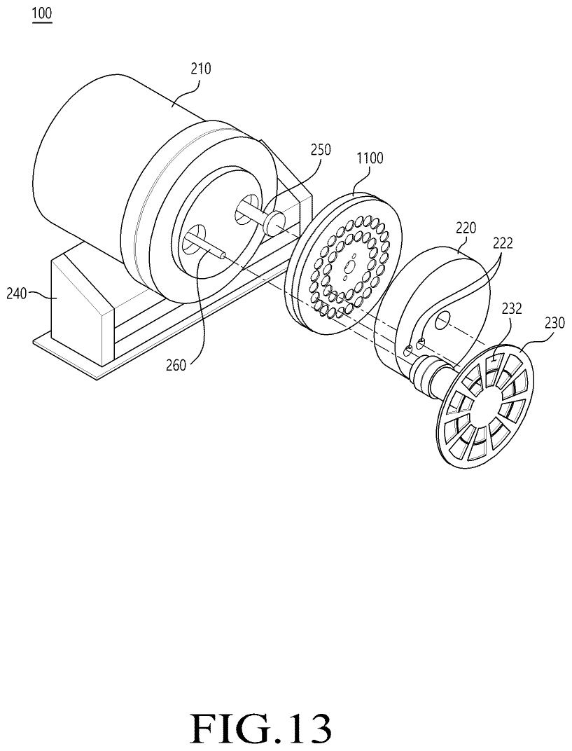

The carousel 1100 according to one embodiment described above can be applied to various sensor modules 100. For example, it can be applied to the sensor module 100 described with reference to FIG. 13, but it is not limited thereto. When applied to a sensor module other than the sensor module 100 described with reference to FIG. 13, the carousel 1100 according to the above-described embodiment can be modified to suit other components of the sensor module.

FIG. 13 is a diagram illustrating the sensor module 100 including the disk 600 according to various example embodiments of the present disclosure.

Referring to FIG. 13, the sensor module 100 may include the carousel 1100, the motor 210, the housing 220, the chopper 230, the fixing device 240, the first shaft 250, and the second shaft 260. However, as the carousel 1100 includes more sensors 330 than the carousel 200, the chopper 230 may not be used or may be removed.

The carousel 1100 may mount the plurality of sensors 330.

The motor 210 may rotate the carousel 1100, the housing 220, or the chopper 230.

The housing 220 may be disposed on the carousel 1100. The housing 220 may include at least one opening.

At least one opening 222 of the housing 220 may overlap with a sensor within the carousel 1100. The at least one opening 222 may include an opening 222 overlapping with at least one sensor among a plurality of sensors 330 within a first region A1 having a first ring shape and an opening 222 overlapping with at least one sensor among a plurality of sensors 330 within a second region A2 having a second ring shape. Accordingly, when the carousel 1100 or the housing 220 is rotated, the plurality of sensors 330 may be sequentially exposed one by one into the chamber 150. The evaporated material may be deposited on one exposed sensor 330. For example, the evaporated material may be deposited on exposed sensor 330 one by one.

The chopper 230 may include at least one opening 232. For example, the size of the opening 232 of the chopper 230 may be different from the size of the opening 222 of the carousel 1100. Accordingly, the amount of material deposited on the sensor 330 may be adjusted. However, the chopper 230 may not be used as the number of sensors 330 increases. Accordingly, cost and material for manufacturing the sensor module 100 can be saved.

The fixing device 240 may fix other components (e.g., the motor 210) in the sensor module 100 to one side in the chamber 150.

The first shaft 250 may be coupled to the carousel 1100 or the housing 220. For example, the motor 210 may be configured to rotate the first shaft 250. Accordingly, based on rotating the first shaft 250, the carousel 1100 or the housing 220 may rotate.

The second shaft 260 may be coupled to the chopper 230. The motor 210 may be configured to rotate the second shaft 260. Accordingly, based on rotating the second shaft 260, the chopper 230 may rotate.

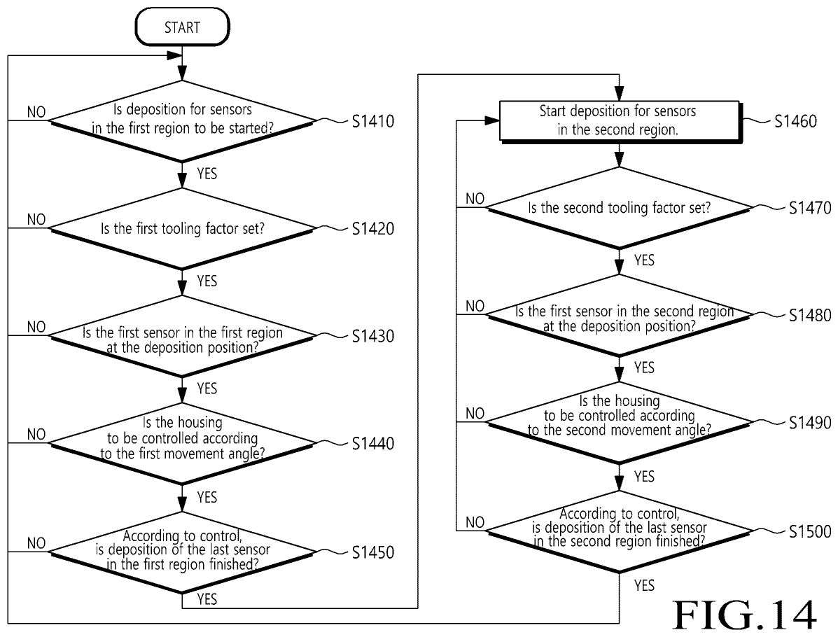

Hereinafter, an operation method of the controller 160 controlling the sensor module 100 according to other example embodiments of the present disclosure described above with reference to FIGS. 6 to 13 will be described with reference to FIG. 14.

FIG. 14 is a flowchart illustrating operations of the controller controlling the sensor module 100 including the disk according to another example embodiment of the present disclosure.

Referring to FIG. 14, in operation S1410, the controller 160 may determine whether to start deposition for the plurality of sensors 330 in the first region A1.

For example, when the thin film deposition process starts, the controller 160 may start deposition for the plurality of sensors 330 in the first region A1.

For example, when a command to start deposition is transmitted from the user terminal 170, the controller 160 may start deposition for the plurality of sensors 330 in the first region A1.

In operation S1420, the controller 160 may determine whether a first tooling factor is set.

For example, if the first tooling factor is not set, the controller 160 may not start deposition.

For example, the first tooling factor may be an offset value according to the position of the sensor 330 in the first region A1. Depending on the position of the sensor 330 in the chamber 150, even if the amount of material evaporated from the crucible 110 is the same, the amount of material deposited on the sensor 330 may change. The first tooling factor may be a value for correcting a deposition amount or deposition rate that varies depending on the position of the sensor 330 in the chamber 150.

For example, the first tooling factor may be a maximum value of a current amount of a signal transmitted from the sensor 330. By adjusting the maximum value of the current amount, identification deviation of the deposition rate according to the position of the sensor 330 may be minimized.

In operation S1430, the controller 160 may determine whether a first sensor in the first region A1 is at a position to be deposited.

For example, the first sensor may be the sensor 330 set to start deposition first in the first region A1.

For example, the position to be deposited may be a position overlapping the opening of the housing 220.

For example, if the first sensor is not at the position to be deposited, the controller 160 may not start deposition.

In operation S1440, the controller 160 may determine whether the housing 220 or the carousel 1100 is set to be controlled according to a first movement angle or a first angular velocity.

For example, since the number of sensors 330 in the first region A1 and the number of sensors 330 in the second region A2 are different, a rotation angle or rotation speed of the housing 220 or the carousel 1100 when depositing using the sensors 330 in the first region A1 may be different from a rotation angle or rotation speed of the housing 220 or the carousel 1100 when depositing using the sensors 330 in the second region A2.

For example, the number of the plurality of sensors 330 in the first region A1 may be 24, and the number of the plurality of sensors 330 in the second region A2 may be 16. At this time, when determining the deposition rate using the plurality of sensors 330 in the first region A1, the housing 220 or the carousel 1100 may rotate by 15 degrees whenever the sensor 330 being deposited is changed. When determining the deposition rate using the plurality of sensors 330 in the second region A2, the housing 220 or the carousel 1100 may rotate by 22.5 degrees whenever the sensor 330 being deposited is changed. However, the number of the plurality of sensors 330 disposed in the first region A1 and the number of the plurality of sensors 330 disposed in the second region A2 are not limited to the presented numbers.

Therefore, the controller 160 needs to check whether the housing 220 or the carousel 1100 is rotated at the first movement angle or the first angular velocity so that the sensors 330 in the first region A1 are sequentially deposited.

For example, if the housing 220 or the carousel 1100 is not set to be controlled according to the first movement angle or the first angular velocity, the controller 160 may not start deposition.

The controller 160 may control the housing 220 or the carousel 1100 according to the first tooling factor, the first sensor position, and the first movement angle (or the first angular velocity) determined in operations S1410 to S1440.

For example, the controller 160 may rotate the housing 220 or the carousel 1100 according to the first movement angle or the first angular velocity so that deposition is sequentially performed from the first sensor in the first region A1 to other sensors in the first region A1. Rotation timing may be changed according to the lifespan of the sensor 330.

In operation S1450, the controller 160 may determine whether deposition of the last or all sensors in the first region A1 is finished as the housing 220 or the carousel 1100 is controlled.

For example, the controller 160 may determine whether the housing 220 or the carousel 1100 has rotated 360 degrees. For example, the controller 160 may determine whether the lifespan of all sensors 330 in the first region A1 has ended.

When deposition of the last or all sensors in the first region A1 is finished, in operation S1460, the controller 160 may determine whether to start deposition for the plurality of sensors 330 in the second region A2.

For example, when the thin film deposition process starts, the controller 160 may start deposition for the plurality of sensors 330 in the second region A2.

For example, when a command to start deposition is transmitted from the user terminal 170, the controller 160 may start deposition for the plurality of sensors 330 in the second region A2.

In operation S1470, the controller 160 may determine whether a second tooling factor is set.

For example, if the second tooling factor is not set, the controller 160 may not start deposition.

For example, the second tooling factor may be an offset value according to the position of the sensor 330 in the second region A2. The second tooling factor may be a value for correcting a deposition amount or deposition rate that varies depending on the position such as the second region A2 of the sensor 330 in the chamber 150.

For example, the second tooling factor may be a maximum value of a current amount of a signal transmitted from the sensor 330. By adjusting the maximum value of the current amount, identification deviation of the deposition rate according to the position of the sensor 330 may be minimized.

In operation S1480, the controller 160 may determine whether a first sensor in the second region A2 is at a position to be deposited.

For example, the first sensor in the second region A2 may be the sensor 330 set to start deposition first in the second region A2.

For example, the position to be deposited may be a position overlapping the opening of the housing 220.

For example, if the first sensor in the second region A2 is not at the position to be deposited, the controller 160 may not start deposition.

In operation S1490, the controller 160 may determine whether the housing 220 or the carousel 1100 is set to be controlled according to a second movement angle or a second angular velocity.

For example, since the number of sensors 330 in the first region A1 and the number of sensors 330 in the second region A2 are different, a rotation angle or rotation speed of the housing 220 or the carousel 1100 when depositing using the sensors 330 in the first region A1 may be different from a rotation angle or rotation speed of the housing 220 or the carousel 1100 when depositing using the sensors 330 in the second region A2.

For example, the number of the plurality of sensors 330 in the first region A1 may be 24, and the number of the plurality of sensors 330 in the second region A2 may be 16. At this time, when determining the deposition rate using the plurality of sensors 330 in the first region A1, the housing 220 or the carousel 1100 may rotate by 15 degrees whenever the sensor 330 being deposited is changed. When determining the deposition rate using the plurality of sensors 330 in the second region A2, the housing 220 or the carousel 1100 may rotate by 22.5 degrees whenever the sensor 330 being deposited is changed. However, the number of the plurality of sensors 330 disposed in the first region A1 and the number of the plurality of sensors 330 disposed in the second region A2 are not limited to the presented numbers.

Therefore, the controller 160 needs to check whether the housing 220 or the carousel 1100 is rotated at the second movement angle or the second angular velocity so that the sensors 330 in the second region A2 are sequentially deposited.

For example, if the housing 220 or the carousel 1100 is not set to be controlled according to the second movement angle or the second angular velocity, the controller 160 may not start deposition.

The controller 160 may control the housing 220 or the carousel 1100 according to the second tooling factor, the second sensor position, and the second movement angle or the second angular velocity determined in operations S1460 to S1490.

For example, the controller 160 may rotate the housing 220 or the carousel 1100 according to the second movement angle or the second angular velocity so that deposition is sequentially performed from the first sensor in the second region A2 to other sensors in the second region A2. Rotation timing may be changed according to the lifespan of the sensor 330.

In operation S1500, the controller 160 may determine whether deposition of the last or all sensors in the second region A2 is finished as the housing 220 or the carousel 1100 is controlled.

For example, the controller 160 may determine whether the housing 220 or the carousel 1100 has rotated 360 degrees. For example, the controller 160 may determine whether the lifespan of all sensors 330 in the second region A2 has ended.

A display device according to example embodiments of the present disclosure may be described as follows.

A sensor mounting device may include a plurality of sensors configured to identify a mass change of a material being deposited, a first holder including a plurality of first openings overlapping the plurality of sensors, a second holder including a plurality of second openings overlapping the plurality of sensors, and a disk on which the plurality of sensors are located, the disk including a plurality of third openings corresponding to respective shapes of the plurality of sensors, and positioned between the first holder and the second holder.

The plurality of third openings in which the plurality of sensors are located may overlap the plurality of first openings and the plurality of second openings, and may be disposed in a first region in the disk having a first ring shape.

The first holder further may include a first central hole, the second holder may further include a second central hole overlapping the first central hole, and the disk may further include a third central hole overlapping the second central hole.

A conductive attachment part attaching the plurality of sensors and the plurality of third openings may be disposed in each of the plurality of third openings.

The disk may further include a second region in which the plurality of third openings in which the plurality of sensors are located are disposed, and which has a second ring shape.

The second region may be disposed closer to the third central hole than the first region, and a diameter of the second ring shape may be smaller than a diameter of the first ring shape.

The plurality of third openings may be additionally disposed in a third region of the disk, the third region has a third ring shape and is positioned between the second region and the third central hole.

A diameter of the second region having the second ring shape may be smaller than a diameter of the first region having the first ring shape and larger than a diameter of the third region having the third ring shape.

A size of the sensor disposed in the plurality of third openings disposed in the second region may be smaller than a size of the sensor disposed in the plurality of third openings disposed in the first region.

The number of the plurality of third openings disposed in the second region may be smaller than the number of the plurality of third openings disposed in the first region.

The first holder may further include a plurality of first openings overlapping the plurality of third openings disposed in the second region.

The second holder may further include a plurality of second openings overlapping the plurality of third openings disposed in the second region.

The second holder may further include a plurality of insulating parts respectively disposed on an inner side and an upper side of the plurality of second openings, and a plurality of spring electrodes contacting the plurality of insulating parts and the plurality of sensors.

The spring electrode may include: a pillar part surrounded by the insulating part; and an electrode part disposed on the insulating part and contacting the plurality of sensors.

The second holder may include a second coupling opening.

The disk may include a third coupling opening overlapping the second coupling opening.

The sensor mounting device may include a fastening part fastened to the second coupling opening and the third coupling opening to couple the disk and the second holder.

The disk may be formed of at least one metal among copper, stainless steel, and iron.

Each of the plurality of sensors may include a quartz layer, a first electrode located on the quartz layer, a second electrode located under the quartz layer and smaller than the first electrode, a first attachment layer located between the quartz layer and the first electrode and to which a material being deposited is attached, and a second attachment layer located between the quartz layer and the second electrode and smaller than the first attachment layer.

The disk may be formed of a metal or alloy having elasticity.

A sensor module may include a carousel on which a plurality of sensors are mounted, a first shaft to which the carousel is coupled, a motor configured to rotate the first shaft, and a housing disposed on the carousel and including an opening overlapping at least one sensor among the plurality of sensors.

The carousel may include a first holder including a plurality of first openings, a second holder including a plurality of second openings overlapping the plurality of first openings, and the plurality of sensors may overlap the plurality of first openings and the plurality of second openings.

The carousel may further include a fastening part, the first holder may further include a first coupling opening coupled to the first shaft, the second holder may further include a second coupling opening, the disk further may further include a third coupling opening overlapping the second coupling opening, and the fastening part may be fastened to the second coupling opening and the third coupling opening to couple the disk and the second holder.

The first holder further may include a first central hole coupled to the first shaft, the second holder may further include a second central hole overlapping the first central hole, and the disk may further include a third central hole overlapping the second central hole, and the second central hole and the third central hole are spaces for the first shaft to pass through.

A second opening among the plurality of second openings may include an insulating part disposed on an inner side and an upper side of the second opening, and a spring electrode surrounded by the insulating part.

The disk may include a first region having a first ring shape and on which the plurality of sensors are mounted, and a second region having a second ring shape having a smaller diameter than the first ring shape and on which a plurality of sensors fewer than the plurality of sensors mounted in the first region are mounted.

The carousel may include a disk on which a plurality of sensors are mounted, a first holder including a plurality of first openings overlapping the plurality of sensors, and a second holder including a plurality of second openings overlapping the plurality of sensors.

It will be apparent to those skilled in the art that various modifications and variations can be made in the sensor mounting device, the sensor module and the deposition apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A sensor mounting device comprising:
a plurality of sensors configured to identify a mass change of a material being deposited;
a first holder including a plurality of first openings overlapping the plurality of sensors;
a second holder including a plurality of second openings overlapping the plurality of sensors; and
a disk including a plurality of third openings on which the plurality of sensors are located, and positioned between the first holder and the second holder,
wherein the plurality of third openings respectively overlap the plurality of first openings and the plurality of second openings, and are disposed in a first region in the disk having a first ring shape.

2. The sensor mounting device of claim 1, wherein the first holder further includes a first central hole, the second holder further includes a second central hole overlapping the first central hole, and the disk further includes a third central hole overlapping the second central hole, and
a conductive attachment part attaching the plurality of sensors and the plurality of third openings is disposed in each of the plurality of third openings.

3. The sensor mounting device of claim 2, wherein the plurality of third openings are additionally disposed in a second region of the disk, wherein the second region has a second ring shape and is positioned between the first region and the third central hole.

4. The sensor mounting device of claim 3, wherein the plurality of third openings are additionally disposed in a third region of the disk, wherein the third region has a third ring shape and is positioned between the second region and the third central hole.

5. The sensor mounting device of claim 4,
wherein a diameter of the second region having the second ring shape is smaller than a diameter of the first region having the first ring shape and larger than a diameter of the third region having the third ring shape.

6. The sensor mounting device of claim 3,
wherein a size of the sensor disposed in the plurality of third openings disposed in the second region is smaller than a size of the sensor disposed in the plurality of third openings disposed in the first region.

7. The sensor mounting device of claim 3,
wherein the first holder further comprises a plurality of first openings overlapping the plurality of third openings disposed in the second region,
wherein the second holder further comprises a plurality of second openings overlapping the plurality of third openings disposed in the second region,
wherein the number of the plurality of third openings disposed in the second region is smaller than the number of the plurality of third openings disposed in the first region.

8. The sensor mounting device of claim 7, wherein the second holder further comprises:
a plurality of insulating parts respectively disposed on an inner side and an upper side of the plurality of second openings; and
a plurality of spring electrodes contacting the plurality of insulating parts and the plurality of sensors.

9. The sensor mounting device of claim 8, wherein the spring electrode includes:
a pillar part surrounded by the insulating part; and
an electrode part disposed on the insulating part and contacting the plurality of sensors.

10. The sensor mounting device of claim 7, further comprising a fastening part, wherein the second holder further comprises a second coupling opening,
wherein the disk further comprises a third coupling opening overlapping the second coupling opening, and
wherein the fastening part is fastened to the second coupling opening and the third coupling opening to couple the disk and the second holder.

11. The sensor mounting device of claim 7, wherein the disk is formed of at least one among copper, stainless steel, and iron.

12. The sensor mounting device of claim 7, wherein each of the plurality of sensors comprises:
a quartz layer;
a first electrode located on the quartz layer;
a second electrode located under the quartz layer and smaller than the first electrode;
a first attachment layer located between the quartz layer and the first electrode and to which a material being deposited is attached; and
a second attachment layer located between the quartz layer and the second electrode and smaller than the first attachment layer.

13. The sensor mounting device of claim 1, wherein the disk is formed of a metal or alloy having elasticity.

14. A sensor module comprising:
a carousel comprising a disk and a plurality of sensors mounted on the disk;
a first shaft to which the carousel is coupled;
a motor configured to rotate the first shaft; and
a housing disposed on the carousel and comprising an opening overlapping at least one sensor among the plurality of sensors.

15. The sensor module of claim 14, wherein the carousel further comprises:
a first holder comprising a plurality of first openings; and
a second holder comprising a plurality of second openings overlapping the plurality of first openings, and
wherein the plurality of sensors overlap the plurality of first openings and the plurality of second openings.

16. The sensor module of claim 15, wherein
the carousel further includes a fastening part,
the first holder further comprises a first coupling opening coupled to the first shaft,
the second holder further comprises a second coupling opening,
the disk further comprises a third coupling opening overlapping the second coupling opening, and
the fastening part is fastened to the second coupling opening and the third coupling opening to couple the disk and the second holder.

17. The sensor module of claim 15, wherein
the first holder further includes a first central hole coupled to the first shaft, the second holder further includes a second central hole overlapping the first central hole, and the disk further includes a third central hole overlapping the second central hole, and
the second central hole and the third central hole are spaces for the first shaft to pass through.

18. The sensor module of claim 15, wherein the second holder further comprises:
a plurality of insulating parts respectively disposed on an inner side and an upper side of the plurality of second openings; and
a plurality of spring electrodes contacting the plurality of insulating parts and the plurality of sensors.

19. The sensor module of claim 14, wherein the plurality of sensors are respectively disposed on a first region of the disk having a first ring shape and a second region of the disk having a second ring shape positioned inside the first ring shape.

20. The sensor module of claim 19, wherein the opening of the housing comprises one opening overlapping at least one of the plurality of sensors in the first region having the first ring shape; and the other opening overlapping at least one of the plurality of sensors in the second region having the second ring shape.

21. A deposition apparatus comprising:
a chamber;
a sensor module disposed within the chamber and comprising a carousel comprising a disk and a plurality of sensors mounted on the disk, and a housing disposed on the carousel and including an opening overlapping at least one of the plurality of sensors; and
a crucible disposed within the chamber and containing a deposition material to be deposited on a substrate within the chamber.
